(19) United States
(12) Patent Application Publication
(10) Pub. No.: US 2016/0204171 A1
(43) Pub. Date: Jul. 14, 2016

(54) ORGANIC LIGHT EMITTING DISPLAY PANEL AND METHOD OF MANUFACTURING THE SAME

(71) Applicant: SAMSUNG DISPLAY CO., LTD., Yongin-si (KR)

(72) Inventors: Seongmin Lee, Asan-si (KR); Hyomin Kim, Cheonan-si (KR); Chiyeoung Shim, Suwon-si (KR)

(21) Appl. No.: 14/934,103

(22) Filed: Nov. 5, 2015

(30) Foreign Application Priority Data
Jan. 14, 2015 (KR) 10-2015-0007041

(51) Int. Cl. H01L 27/32; H01L 51/56

(52) U.S. Cl. CPC H01L 27/3246; H01L 51/56; H01L 51/5206

(57) ABSTRACT

An organic light emitting display panel includes a base substrate; a light emitting device comprising a first electrode, a light emitting layer on the first electrode, and a second electrode on the light emitting layer; a base layer providing a base surface on which the first electrode is located; a supporting layer protruding from the base surface; a sub-electrode spaced from the first electrode, electrically connected to the second electrode, and located on the supporting layer; and a pixel definition layer on the base substrate so as to expose the first electrode and the sub-electrode.

### CROSS-REFERENCE TO RELATED APPLICATION

This patent application claims priority to and the benefit of Korean Patent Application No. 10-2015-0007041, filed on Jan. 14, 2015, the contents of which are hereby entirely incorporated by reference.

### BACKGROUND

1. Field

The present disclosure relates to an organic light emitting display panel and a method of manufacturing the same.

2. Description of the Related Art

An organic light emitting display device includes a display panel including an anode electrode, a cathode electrode, and a light emitting layer disposed between the anode and cathode electrodes and including an organic material. Among display devices, the organic light emitting display device has been spotlighted as a next generation display device for its wide viewing angle and fast response time.

The organic light emitting display device is classified into a front surface light-emitting type and a rear surface light-emitting type according to a transmission direction of light. The front surface light-emitting type organic light emitting display device typically has an aperture ratio higher than the rear surface light-emitting type organic light emitting display device.

However, since the light travels through the cathode electrode in the front surface light-emitting type organic light emitting display device, the cathode electrode includes a conductive material, but is required to have transmittance. The semi-transmission material has a thin thickness, and thus there is a limitation to realize a low resistance cathode electrode.

Accordingly, a voltage drop, i.e., an IR drop, may occur in the cathode electrode, and particularly, the voltage drop may be intensified according to the increase in area of the organic light emitting display device.

### SUMMARY

The present disclosure provides an organic light emitting display panel capable of preventing a voltage drop from occurring and having improved optical characteristic.

The present disclosure provides a method of manufacturing the organic light emitting display panel.

Embodiments of the inventive concept provide an organic light emitting display panel including a base substrate, a light emitting device including a first electrode, a light emitting layer disposed on the first electrode, and a second electrode disposed on the light emitting layer, a base layer providing a base surface on which the first electrode is disposed, a supporting layer protruded from the base surface, a sub-electrode spaced from the first electrode, electrically connected to the second electrode, and disposed on the supporting layer, and a pixel definition layer disposed on the base substrate to expose the first electrode and the sub-electrode.

A portion at which the second electrode contacts the sub-electrode is overlapped with the supporting layer.

The supporting layer includes a supporting surface supporting the contact portion of the second electrode and the sub-electrode and an inclination surface inclined from the supporting surface.

The sub-electrode is overlapped with the supporting surface and the inclination surface.

The supporting layer and the pixel definition layer are disposed on the base surface.

The supporting layer has substantially the same thickness as the pixel definition layer.

The sub-electrode includes at least one of a first portion corresponding to one side of the first electrode and a second portion corresponding to the other side of the first electrode when viewed in a plan view.

The supporting layer includes at least one of a first pattern corresponding to the first portion and a second pattern corresponding to the second portion.

The supporting layer includes a plurality of island patterns overlapped with the first portion or the second portion.

The first electrode has substantially the same thickness as the sub-electrode.

The first electrode includes substantially the same material as the sub-electrode.

The first electrode has substantially the same layer structure as the sub-electrode.

The supporting layer and the base layer are integrally formed with each other in a single unitary and individual unit.

The supporting layer includes an organic material or an inorganic material.

Embodiments of the inventive concept provide a method of manufacturing an organic light emitting display panel, including forming an insulating layer including a first portion providing a base surface and a second portion protruded from the base surface on a base substrate, forming a conductive layer on the insulating layer, patterning the conductive layer to form a first electrode on the base surface and a sub-electrode spaced from the first electrode and disposed on the second portion, forming a pixel definition layer on the base surface to expose the first electrode and the sub-electrode, forming a light emitting layer on the first electrode, and forming a second electrode electrically connected to the sub-electrode.

The forming of the insulating layer includes disposing a base layer providing the base surface on the base substrate to form the first portion and forming a second portion on the base surface.

The forming of the second portion includes forming a preliminary supporting layer on the base layer and removing areas of the preliminary supporting layer except for an area overlapped with a portion at which the sub-electrode contacts the second electrode.

The forming of the pixel definition layer includes forming a preliminary pixel definition layer on the base surface and forming openings through the preliminary pixel definition layer to respectively expose the first electrode and the sub-electrode.

An opening among the openings, which exposes the sub-electrode, is formed by a laser drilling method.

The forming of the insulating layer includes forming a preliminary insulating layer on the base substrate and removing the preliminary insulating layer in different thicknesses to allow the first and second portions to be formed from the preliminary insulating layer.

According to the above, the organic light emitting display panel further includes the sub-electrode disposed under the second electrode and the sub-electrode is electrically connected to the second electrode. The voltage having the same level as the voltage applied to the second electrode is applied to the sub-electrode, and thus the voltage drop may be prevented from occurring in the sub-electrode. Therefore, brightness of the organic light emitting display panel may be prevented from being varied due to areas of the organic light emitting display panel.

The sub-electrode is formed through the same process as a formation process of the first electrode. The supporting layer disposed under the contact portion of the second electrode and the sub-electrode planarizes the surface of the second electrode, and thus the reflectance of the external light is reduced. Thus, the visibility of the organic light emitting display panel is improved.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a cross-sectional view showing an organic light emitting display panel according to an exemplary embodiment of the present disclosure;

FIG. 2 is an equivalent circuit diagram showing a pixel according to an exemplary embodiment of the present disclosure;

FIG. 3 is a plan view showing an organic light emitting display panel according to an exemplary embodiment of the present disclosure;

FIG. 4 is a cross-sectional view showing an organic light emitting display panel according to an exemplary embodiment of the present disclosure;

FIG. 5 is a plan view showing an organic light emitting display panel according to an exemplary embodiment of the present disclosure;

FIG. 6 is a plan view showing an organic light emitting display panel according to an exemplary embodiment of the present disclosure;

FIG. 7 is a cross-sectional view showing an organic light emitting display panel according to an exemplary embodiment of the present disclosure;

FIGS. 8A to 8H are cross-sectional view showing a method of manufacturing an organic light emitting display panel according to an exemplary embodiment of the present disclosure;

FIG. 9 is a cross-sectional view showing an organic light emitting display panel according to an exemplary embodiment of the present disclosure; and

FIGS. 10A to 10G are cross-sectional view showing a method of manufacturing an organic light emitting display panel according to an exemplary embodiment of the present disclosure.

### DETAILED DESCRIPTION

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

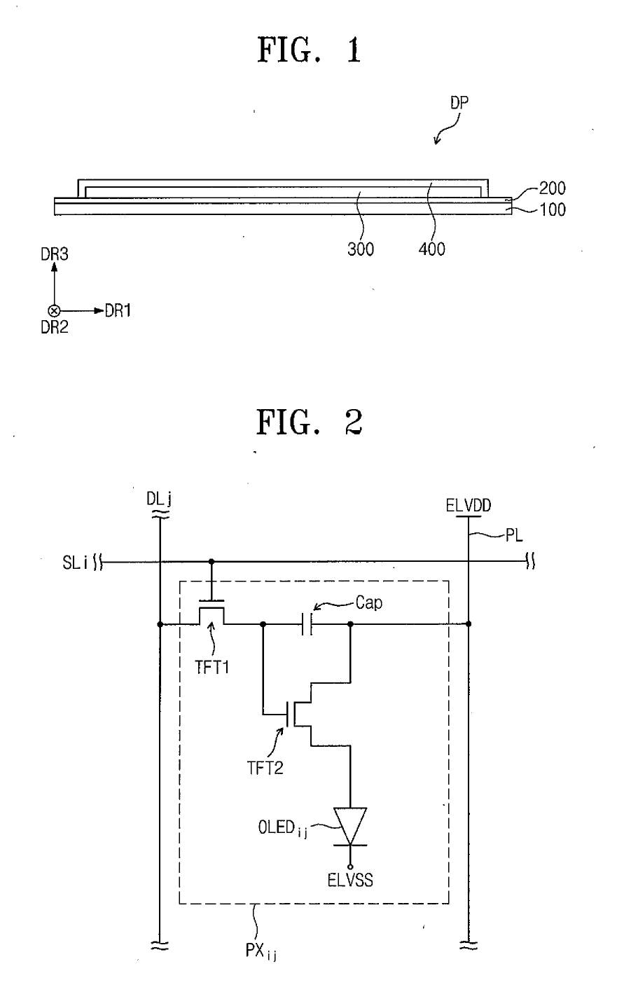

FIG. 1 is a cross-sectional view showing an organic light emitting display panel DP (hereinafter, referred to as a display panel) according to an exemplary embodiment of the present disclosure and FIG. 2 is an equivalent circuit diagram showing a pixel PX according to an exemplary embodiment of the present disclosure.

Referring to FIG. 1, the display panel DP includes a base member 100, a circuit layer 200, a device layer 300, and an encapsulation layer 400. The display panel DP may further include an optical member layer disposed on the encapsulation layer 400, e.g., a phase retardation layer, a polarization layer, etc. In addition, the display panel DP may further include a touch sensor layer disposed above the encapsulating layer 400. Hereinafter, a first direction DR1 and a second direction DR2 define a front surface of the display panel DP and a third direction DR3 indicates a thickness direction of the display panel DP.

The base member 100 includes at least one plastic film. In one embodiment, the base member 100 includes two plastic films, inorganic layers, a silicon nitride layer and/or a silicon oxide layer, which are disposed between the two plastic films. The base member 100 includes at least one of polyimide (PI), polyethyleneterephthalate (PET), polyethylenenaphthalate (PEN), polyethersulphone

(PES), and fiber reinforced plastics (FRP).

The circuit layer 200 includes signal lines and electronic devices, which are disposed on the display panel DP. The circuit layer 200 includes insulating layers to insulate the signal lines and the electronic devices.

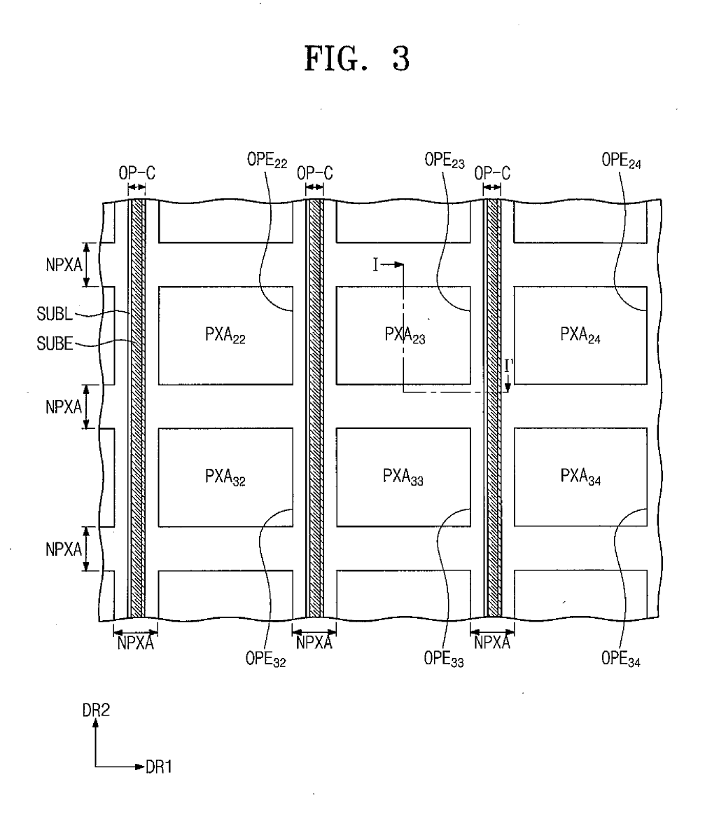

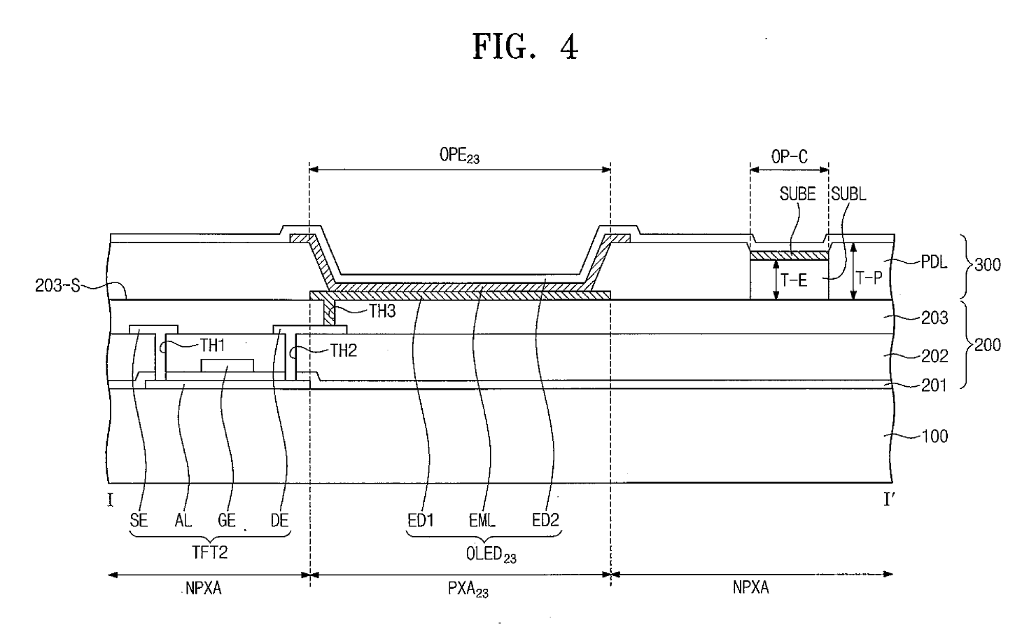

The device layer 300 includes light emitting devices. The light emitting devices include an organic light emitting diode OLED (refer to FIG. 2). The device layer 300 may further include elements to assist the organic light emitting diode. In the present exemplary embodiment, the elements include a sub-electrode SUBE (refer to FIGS. 3 and 4). The circuit layer 300 may further include insulating layers to insulate the light emitting device and the element assisting the light emitting device or to separate the light emitting device and the element assisting the light emitting device.

The encapsulating layer 400 encapsulates the device layer 300. The encapsulation layer 400 includes one or more inorganic thin film layers or one or more organic thin film layers and has a structure in which the inorganic thin film layers and the organic thin film layers are alternately stacked. In the present exemplary embodiment, the encapsulation layer 400 may be replaced with a glass or film. The encapsulation layer 400 is spaced from the base member 100 such that the device layer 300 is disposed between the base member 100 and the encapsulation layer 400. A sealing agent is provided along edges of the encapsulation layer 400 and the base member 100 to form a space.

Referring to FIG. 2, the pixel PX includes at least one transistor, at least one capacitor, and an organic light emitting diode. FIG. 2 shows the equivalent circuit diagram of an i-th scan line Si among scan lines, a j-th data line Dj among data lines, and a pixel PXᵢⱼ connected to a power source line PL as a representative example.

The pixel PXᵢⱼ includes a first transistor TFT1, a second transistor TFT2, a capacitor Cap, and an organic light emitting diode OLEDᵢⱼ. The first transistor TFT1 outputs a data signal applied to the j-th data line Dj in response to a scan signal applied to the i-th scan line Si. The capacitor Cap is charged with electric charges corresponding to a difference between a voltage corresponding to the data signal provided from the first transistor TFT1 and a first source voltage ELVDD provided through the power source line PL.

The second transistor TFT2 controls a driving current flowing through the organic light emitting diode OLEDᵢⱼ in response to the amount of the electric charges charged in the capacitor Cap. A turn-on time period of the second transistor TFT2 is determined depending on the amount of the electric charges charged in the capacitor Cap.

The organic light emitting diode OLEDᵢⱼ includes a first electrode ED1 (refer to FIG. 4) connected to the second transistor TFT2 and a second electrode ED2 (refer to FIG. 4) receiving a second source voltage ELVSS. The organic light emitting diode OLEDᵢⱼ emits the light during the turn-on period of the second transistor TFT2. The light emitted from the organic light emitting diode OLEDᵢⱼ has a color determined by a material included in the organic light emitting layer. For instance, the color of the light emitted from the organic light emitting diode OLEDᵢⱼ may be a red, green, blue, or white color.

The i-th scan line Si, the j-th data line Dj, the first transistor TFT1, the second transistor TFT2, and the capacitor Cap are included in the circuit layer 200 shown in FIG. 1. The organic light emitting diode OLEDᵢⱼ is included in the device layer 300 shown in FIG. 1.

FIG. 3 is a plan view showing an organic light emitting display panel according to an exemplary embodiment of the present disclosure and FIG. 4 is a cross-sectional view showing an organic light emitting display panel according to an exemplary embodiment of the present disclosure, which is taken along a line I-I′ of FIG. 3.

For the convenience of explanation, FIG. 3 shows a portion of elements of the display panel DP. FIG. 3 shows six light emitting areas PXA22 to PXA34, three sub-electrodes SUBE, and a supporting layer SUBL corresponding to the three sub-electrodes SUBE. To distinguish the supporting layer SUBL from the sub-electrodes SUBE, a width in the first direction DR1 of the supporting layer SUBL is shown different from a width in the first direction DR1 of the sub-electrodes SUBE in FIG. 3.

Referring to FIG. 3, the display panel DP includes a plurality of light emitting areas PXA₂₂ to PXA₃₄ and a non-light emitting area NPXA disposed adjacent to the light emitting areas PXA₂₂ to PXA₃₄, which are defined on the front surface defined by the first and second directions DR1 and DR2. The non-light emitting area NPXA corresponds to an area in which a pixel definition layer PDL (refer to FIG. 4) is disposed, and the light emitting areas PXA₂₂ to PXA₃₄ correspond to pixel openings OPE₂₂ to OPE₃₄ of the pixel definition layer PDL. The pixel definition layer PDL is provided with a connection opening OP-C formed therethrough to connect the sub-electrode SUBE and the second electrode of the organic light emitting diode.

The light emitting areas PXA₂₂ to PXA₃₄ are surrounded by the non-light emitting area NPXA. Each of the light emitting areas PXA₂₂ to PXA₃₄ includes the organic light emitting diode of the corresponding pixel disposed therein. The first electrode ED1 (refer to FIG. 4) of the organic light emitting diode has the same shape as a corresponding light emitting area of the light emitting areas. In the present exemplary embodiment, the first electrode ED1 may be an anode electrode.

The sub-electrode SUBE and the supporting layer SUBL supporting the sub-electrode SUBS are disposed in the non-light emitting area NPXA. The sub-electrode SUBE and the supporting layer SUBL may have the same shape. The sub-electrode SUBE and the supporting layer SUBL are oriented to be substantially parallel to one side of the first electrode ED1. As shown in FIG. 3, the sub-electrode SUBE and the supporting layer SUBL have a stripe shape extending in the second direction DR2. In the present exemplary embodiment, the sub-electrode SUBE may be partially overlapped with the supporting layer SUBL.

The connection opening OP-C has the same shape as the support layer

SUBL. Accordingly, the sub-electrode SUBE is fully exposed through the pixel definition layer PDL. When the area in which the sub-electrode SUBE is connected to the second electrode ED2 increases, the second source voltage ELVSS is easily applied to the second electrode ED2 from the sub-electrode SUBE. Therefore, a voltage drop occurs in the second electrode ED2. In the present exemplary embodiment, the connection opening OP-C partially exposes the sub-electrode SUBE.

Referring to FIG. 4, the thin film transistor TFT2 is disposed on the base substrate 100. FIG. 4 shows the second transistor TFT2 of the first and second transistors TFT1 and TFT2 shown in FIG. 2 as a representative example. The thin film transistor TFT2 includes a semiconductor layer AL, a gate electrode GE, a source electrode SE connected to the semiconductor layer AL, and a drain electrode

DE connected to the semiconductor layer AL.

The semiconductor layer AL is disposed on the base substrate 100. In this case, a buffer layer may be further disposed on the base substrate 100 before the semiconductor layer AL is formed.

The semiconductor layer AL is formed of an amorphous silicon thin film or a polysilicon thin film, but it should not be limited thereto or thereby. For instance, the semiconductor layer AL may include organic semiconductor or oxide semiconductor. In one embodiment, the semiconductor layer AL includes a source region highly doped with an n-type impurity, a drain region highly doped with a p-type impurity, and a channel region disposed between the source region and the drain region.

A gate insulating layer 201 is disposed on the semiconductor layer AL. The gate insulating layer 201 insulates the semiconductor layer AL from layers formed through the following process. The gate insulating layer 201 includes an inorganic insulating layer, such as a silicon oxide material, a silicon nitride material, an aluminum oxide material. According to embodiments, the gate insulating layer 201 may be an organic insulating layer containing a polymer material, such as polymethylmethacrylene, polystyrene, phenol-based polymer, acryl-based polymer, polyimide, polyvinyl, etc.

The gate electrode GE is disposed on the gate insulating layer 201 and is connected to the corresponding scan line. The gate electrode GE includes a polysilicon or a conductive metal material, such as molybdenum fluoride, aluminum, chromium, aluminum/chromium, etc. As another example, the gate electrode GE may include a conductive polymer, such as a conductive polyaniline, a conductive polypyrrole, a conductive polythiophen, a polystyrene sulfonic acid, etc.

A first insulating layer 202 is disposed on the gate electrode GE. The first insulating layer 202 covers the gate electrode GE and electrically insulates the gate electrode GE from other elements. The first insulating layer 202 includes a first contact hole TH1 and a second contact hole TH2, which are spaced from each other.

The source electrode SE and the drain electrode DE are disposed on the first insulating layer 202 and spaced from each other. The source electrode SE and the drain electrode DE are connected to the semiconductor layer AL respectively through the first and second contact holes TH1 and TH2.

In the present exemplary embodiment, the thin film transistor TFT2 has a bottom gate structure in which the gate electrode GE is disposed under the source electrode SE and the drain electrode DE. In this case, the semiconductor layer AL is disposed on the source electrode SE and the drain electrode DE. In the present exemplary embodiment, a driving method of the thin film transistor TFT2 should not be limited to a specific driving method.

A second insulating layer 203 is disposed on the first insulating layer 202 to cover the source electrode SE and the drain electrode DE. The first electrode ED1 is disposed on the second insulating layer 203. In the present exemplary embodiment, the second insulating layer 203 directly supporting the first electrode ED1 is referred to as a base layer. In addition, an upper surface of the second insulating layer 203 is referred to as a base surface 203-S.

The first electrode ED1 is connected to the drain electrode DE through a contact hole TH3 formed through the base layer 203. The first electrode EDI includes a material having high conductivity and high work function. The first electrode ED1 includes a transparent conductive oxide material, e.g., indium tin oxide, indium zinc oxide, zinc oxide, indium oxide, etc. In addition, the first electrode ED1 may have a multi-layer structure of a metal layer having high reflectance and a transparent conductive layer.

The pixel definition layer PDL and the supporting layer SUBL are disposed on the base surface 203-S. FIG. 4 shows one of the pixel openings OPE₂₂ to OPE₃₄ and one of the connection openings OP-C shown in FIG. 3. An organic light emitting layer EML is disposed on the first electrode ED1 to overlap with the one opening. The organic light emitting layer EML generates one of red, green, blue, and white colors. The organic light emitting layer EML includes a fluorescent material or a phosphorescent material.

In the present exemplary embodiment, a first common layer is further disposed between the first electrode ED1 and the organic light emitting layer EML. The first common layer is disposed to overlap with the light emitting areas PXA₂₂ to PXA₃₄ (refer to FIG. 3) and the non-light emitting area NPXA (refer to FIG. 3). The first common layer controls a mobility of holes injected from the first electrode ED1. The first common layer includes a hole injection layer. The first common layer may further include a hole transport layer.

The supporting layer SUBL is protruded from the base substrate 203-S and overlapped with a portion of the base substrate 203-S. The supporting layer SUBL includes an organic or inorganic material. The supporting layer SUBL contacts the pixel definition layer PDL. The sub-electrode SUBE is disposed on the supporting layer SUBL. The sub-electrode SUBE has the same thickness, material, and layer structure as those of the first electrode ED1 and the sub-electrode SUBE and the first electrode ED1 may be formed through the same process as described later.

The second electrode ED2 is disposed on the pixel definition layer PDL. The second electrode ED2 is connected to the organic light emitting layer EML and the sub-electrode SURE. The second electrode ED2 includes a material having a work function lower than the first electrode ED1. For instance, the second electrode ED2 may be a reflective electrode including lithium, calcium, lithiumflouride/calcuim, lithiumfluoride/aluminum, aluminum, silver, magnesium, or a compound thereof. As another example, the second electrode ED2 may be a transparent electrode. For instance, the second electrode ED2 may be formed of a transflective thin film layer containing silver.

The second electrode ED2 is formed by a deposition process as a thin film layer. In particular, when the display panel DP is the front surface light-emitting type, the second electrode ED2 has a thickness of about 100 angstroms in order to improve the transmittance of the display panel DP. When the thickness of the second electrode ED2 becomes thin, an internal resistance of the second electrode ED2 increases. In a large-sized display panel, the second electrode ED2 is deposited on an entire surface of the display panel. The second electrode ED2 receives the second source voltage ELVSS or a sub-voltage having a voltage level similar to the second source voltage ELVSS from the sub-electrode SUBE.

The second electrode ED2 is disposed to overlap with the light emitting areas PX22 to PXA34 (refer to FIG. 3) and the non-light emitting area NPXA (refer to FIG. 3). In the present exemplary embodiment, a second common layer is further disposed between the organic light emitting layer EML and the second electrode ED2. The second common layer is disposed to overlap with the light emitting areas PX22 to PXA34 (refer to FIG. 3) and the non-light emitting area NPXA (refer to FIG. 3). The second common layer controls a mobility of electrons. The second common layer includes an electron injection layer. The second common layer further includes an electron transport layer disposed between the electron injection layer and the organic light emitting layer EML.

The supporting layer SUBL and the pixel definition layer PDL have substantially the same thicknesses T-E and T-P. Here, the term of “having the substantially same thicknesses” used herein means that the supporting layer SUBL and the pixel definition layer PDL are designed to have substantially the same thicknesses in consideration of process errors.

Since the supporting layer SUBL has substantially the same thickness as that of the pixel definition layer PDL, the sub-electrode SUBE formed through the same process as the first electrode ED1 is disposed adjacent to the second electrode ED2. The portion in which the second electrode ED2 is connected to the sub-electrode SUBL is overlapped with the supporting layer SUBL.

According to a comparison example in which the sub-electrode SUBE is disposed on the base surface 203-S, recesses, holes, or cavities are formed to electrically connect the second electrode ED2 and the sub-electrode SUBE. The recesses, holes, or cavities cause concavo-convex portions in the viewpoint of the second electrode ED2. The concavo-convex portions cause diffused reflection. Therefore, a reflectance of external light increases. According to the present exemplary embodiment, the supporting layer SUBL shifts the sub-electrode SURE to the second electrode ED2 from the base surface 203-S, and thus the second electrode ED2 has a relatively flat surface when compared to the comparison example. Thus, the reflectance of the external light decreases.

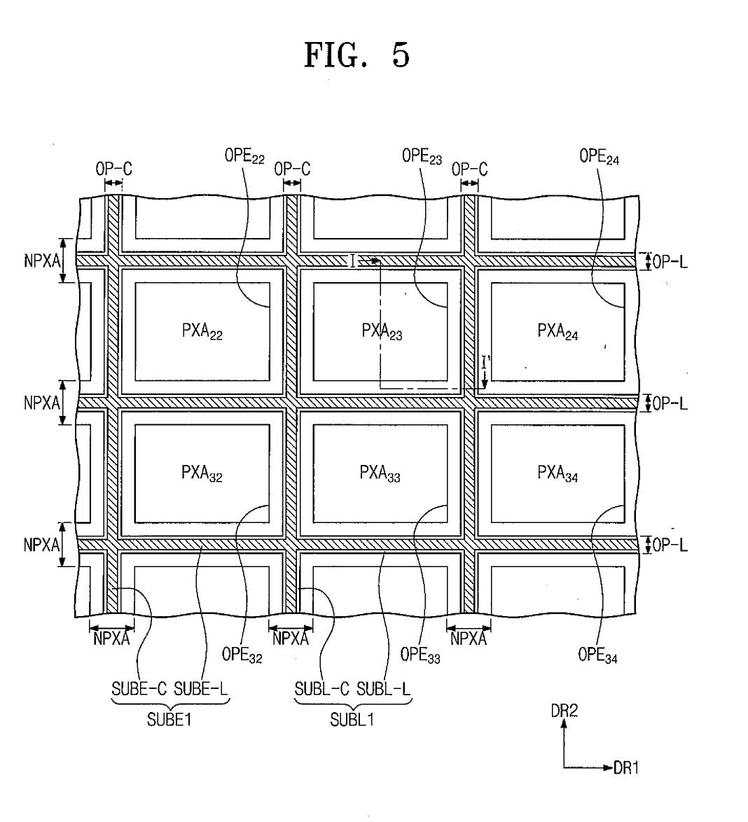

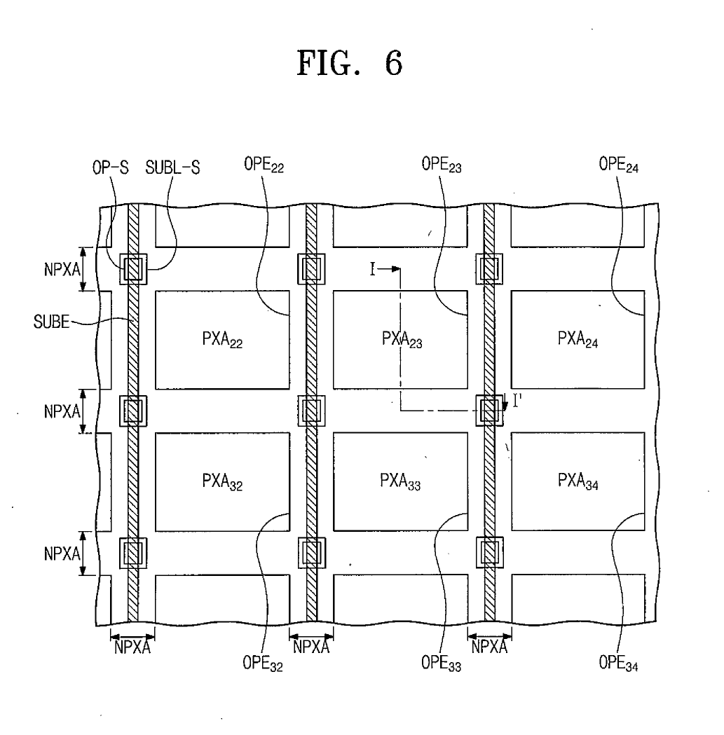

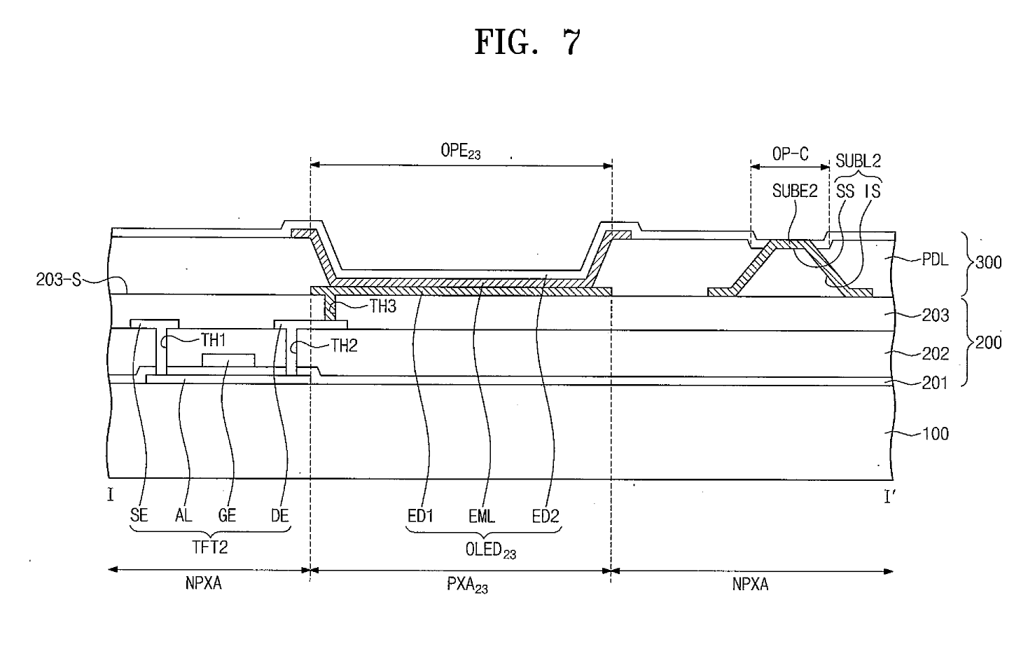

FIG. 5 is a plan view showing an organic light emitting display panel according to an exemplary embodiment of the present disclosure, FIG. 6 is a plan view showing an organic light emitting display panel according to an exemplary embodiment of the present disclosure, and FIG. 7 is a cross-sectional view showing an organic light emitting display panel according to an exemplary embodiment of the present disclosure. In FIGS. 5 to 7, the same reference numerals denote the same elements in FIGS. 1 to 4, and thus detailed descriptions of the same elements will be omitted.

Referring to FIG. 5, a sub-electrode SUBE1 includes a first portion SUBE-C corresponding to one side of the first electrode ED1 (refer to FIG. 4) and a second portion SUBE-L corresponding to the other side of the first electrode ED1 when viewed in a plan view. The sub-electrode SUBE1 has a mesh shape.

A supporting layer SUBL1 has substantially the same shape as the sub-electrode SUBE1. The supporting layer SUBL1 includes a first pattern SUBL-C corresponding to the first portion SUBE-C and a second pattern SUBL-LE_{P2} corresponding to the second portion SUBE-L.

Referring to FIG. 6, a supporting layer SUBL-S includes a plurality of island patterns overlapped with the first portion SUBE-C. A plurality of connection openings OP-S is formed through the pixel definition layer PDL to correspond to the island patterns. In the present exemplary embodiment, the first portion SUBE-C may be replaced with the second portion SUBE-L.

A supporting layer SUBL2 may have various shapes. For instance, the supporting layer SUBL2 may have a circular shape or a polygonal shape when viewed in a cross-sectional view.

Referring to FIG. 7, the supporting layer SUBL2 includes a supporting surface SS supporting the portion at which the second electrode ED2 contacts the sub-electrode SUBE and an inclination surface IS inclined from the supporting surface SS. A sub-electrode SUBE2 disposed on the supporting layer SUBL2 may be disposed not only on the supporting surface SS but also on the inclination surface IS. In the present exemplary embodiment, the sub-electrode SUBE2 may be disposed only on the supporting surface SS.

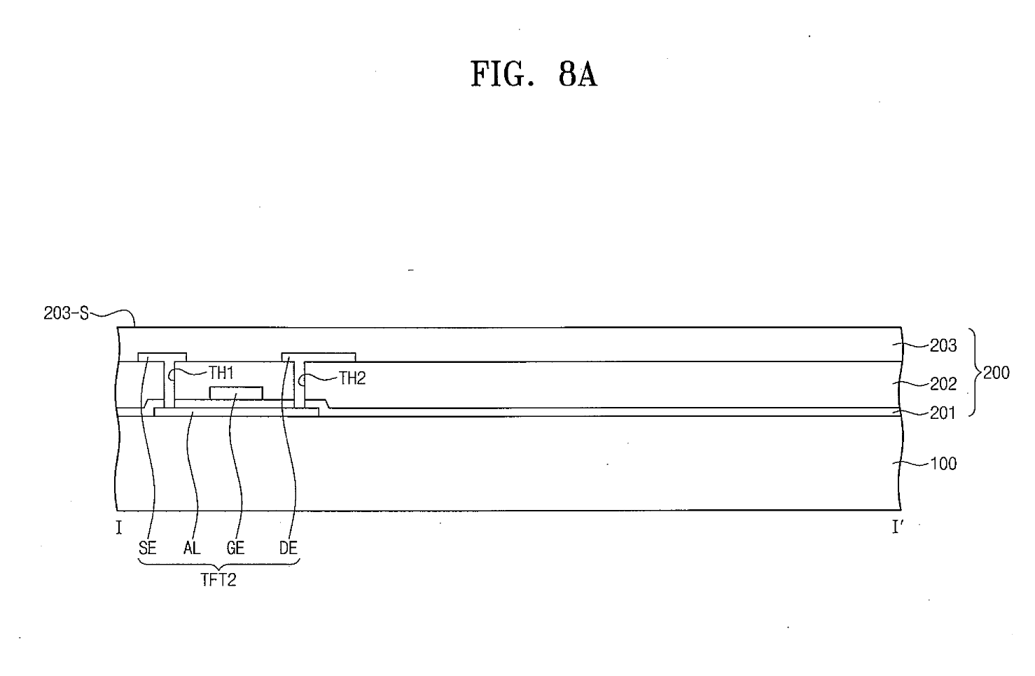

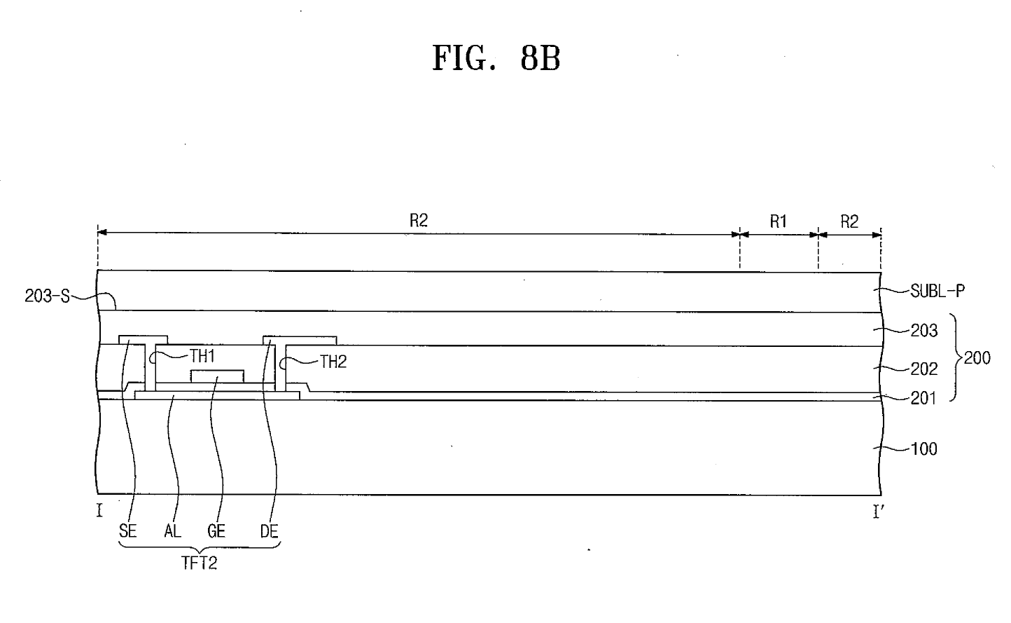

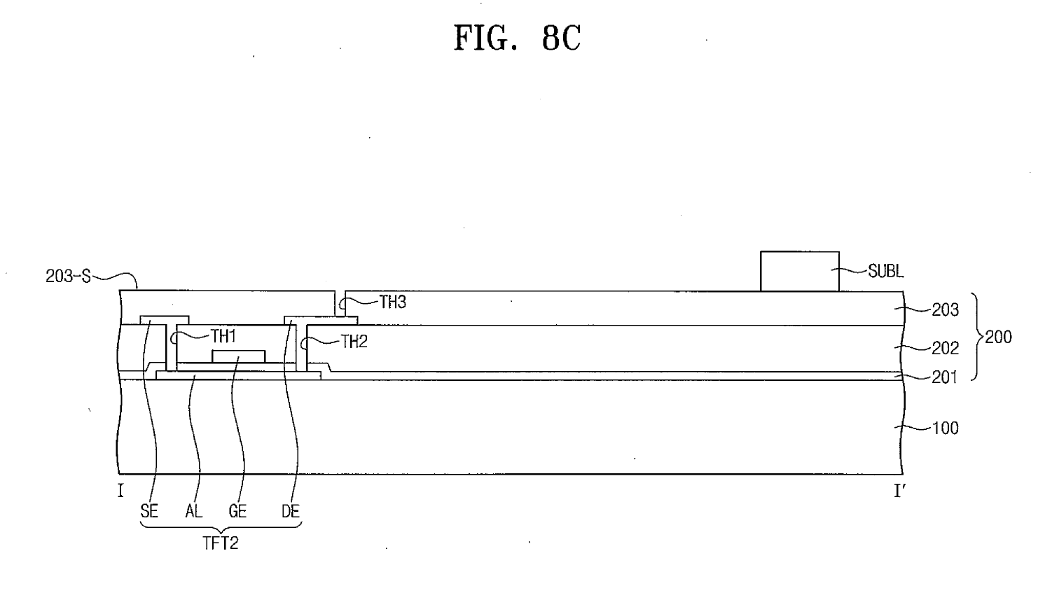

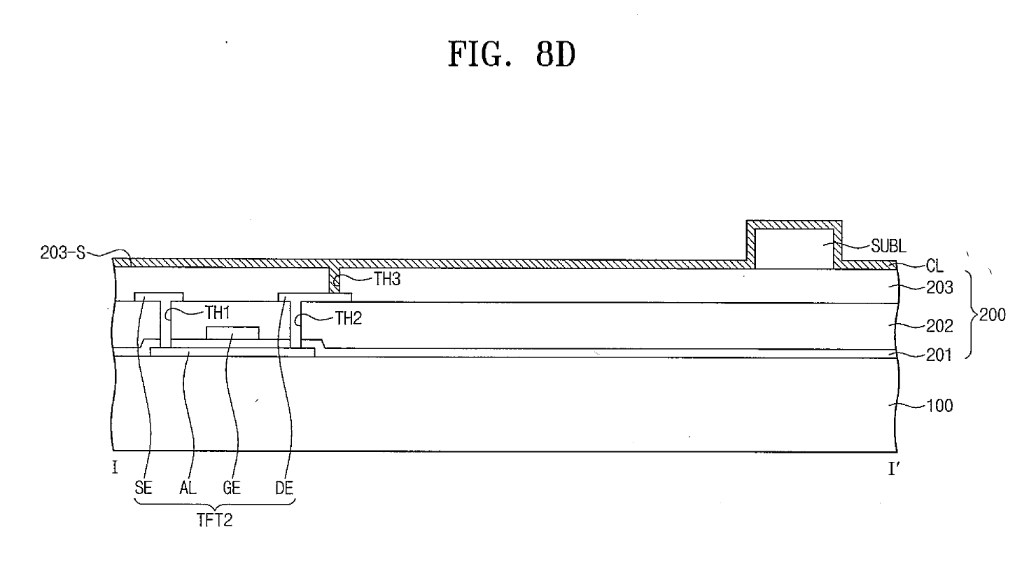

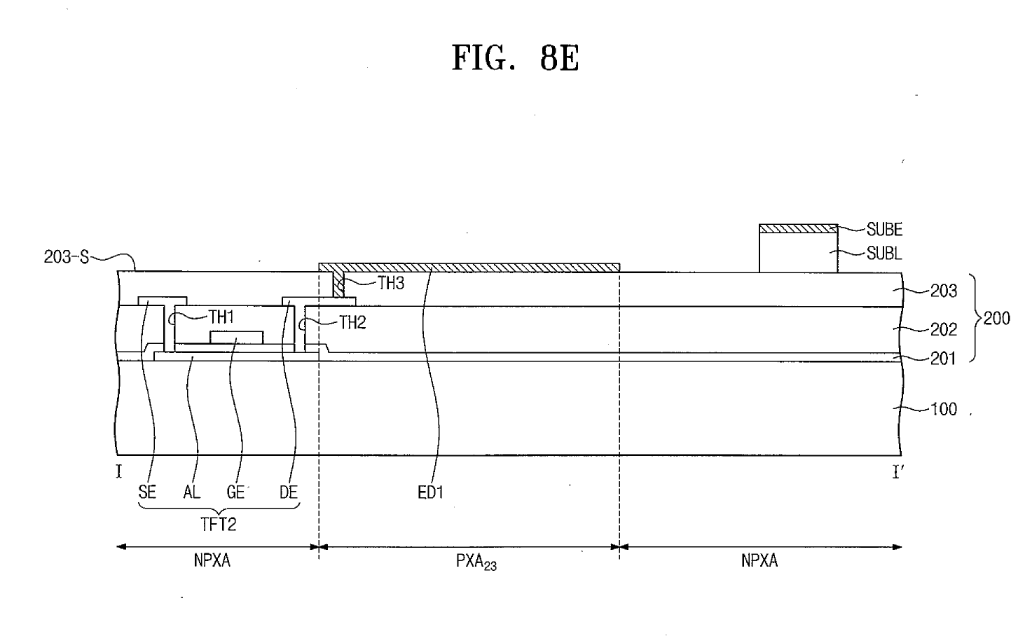

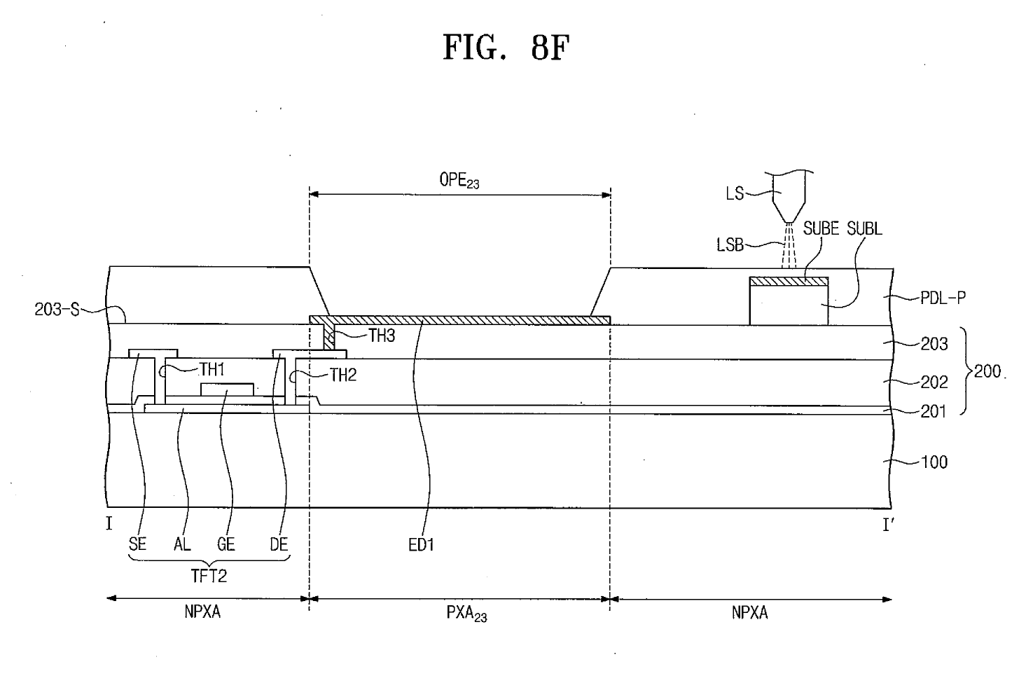

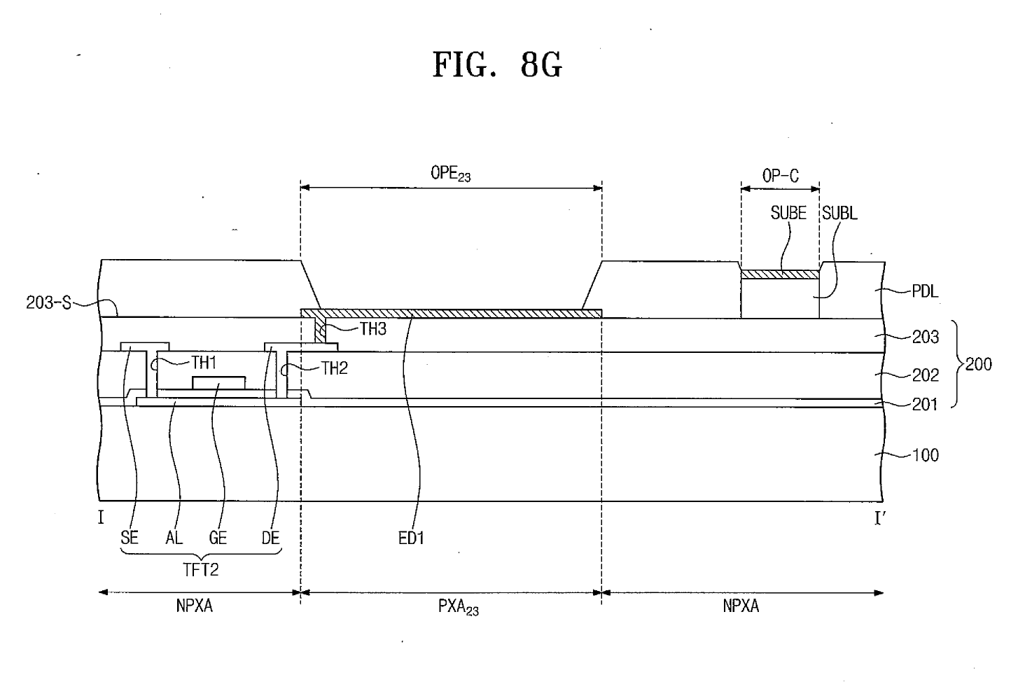

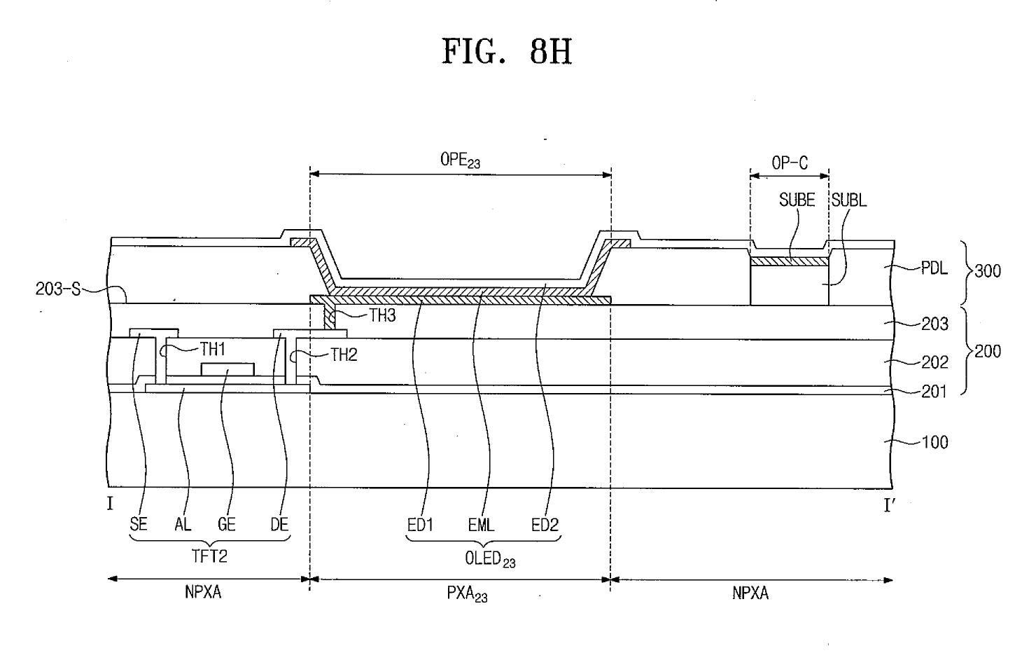

FIGS. 8A to 8H are cross-sectional view showing a method of manufacturing an organic light emitting display panel according to an exemplary embodiment of the present disclosure. FIGS. 8A to 8H show the cross-sectional view shown in FIG. 4.

As shown in FIGS. 8A to 8C, a first portion 203 providing the base surface 203-S and a second portion SUBL protruded from the base surface 203-S are formed on the base substrate 100.

Referring to FIG. 8A, the base layer 203 is formed on the base substrate 100 to cover the thin film transistor TFT2. The base layer 203 is the insulating layer and includes an inorganic or organic material. The base layer 203 is formed through a deposition, coating, or printing process.

The thin film transistor TFT and the insulating layers 201 and 202, which are disposed under the base layer 203, are formed prior to the base layer 203. The thin film transistor TFT2 is formed on the base substrate 100 through several photolithography processes. In this case, other circuits of the pixels, e.g., the data lines, the gate lines, the capacitor, and other thin film transistors, are substantially and simultaneously formed together with the thin film transistor TFT2. The insulating layers 201 and 202 are formed through several deposition or coating processes.

Referring to FIG. 8B, a preliminary supporting layer SUBL-P is formed on the base layer 203-S. The preliminary supporting layer SUBL-P includes an organic or inorganic material and is formed by a deposition, coating, or printing process. The preliminary supporting layer SUBL-P is divided into a remaining portion R1 and a removing portion R2. The remaining portion R1 corresponds to the portion at which the sub-electrode and the second electrode are connected to each other and is designed in advance.

Referring to FIG. 8C, the supporting layer SUBL is formed from the preliminary supporting layer SUBL-P. The portion R2 of the preliminary supporting layer SUBL-P is removed.

Referring to FIG. 8D, a conductive layer CL is formed. The conductive layer CL covers the base surface 203-S and the supporting layer SUBL. The conductive layer CL is formed through a coating, plating, or depositing process. The conductive layer CL has a multi-layer structure.

Referring to FIG. 8E, the first electrode ED1 disposed on the base surface 203-S and the sub-electrode SUBE spaced from the first electrode ED1 are formed from the conductive layer CL. The conductive layer CL is patterned by exposure and development processes.

Referring to FIG. 8F, a preliminary pixel definition layer PDL-P is formed on the base surface 203-S. The preliminary pixel definition layer PDL-P includes an organic or inorganic material and is formed through a depositing, coating, or printing process.

Referring to FIG. 8G, the openings OPE₂₃ and OP-C are formed through the preliminary pixel definition layer PDL-P to respectively expose the first electrode ED1 and the sub-electrode SUBE.

As shown in FIGS. 8F and 8G, the connection opening OP-C is formed by a laser drilling method. A laser beam LSB irradiated from a laser gun LS partially removes the preliminary pixel definition layer PDL-P. The pixel opening OPE₂₃ shown in FIG. 8F may be formed by the laser drilling method.

In one embodiment, the connection opening OP-C may be formed after the following processes are carried out. For instance, the connection opening OP-C may be formed after at least one of the first common layer, the organic light emitting layer EML, and the second common layer is formed on the first electrode ED1. The connection opening OP-C is required to be formed before the second electrode ED2 is formed.

Referring to FIG. 8H, the light emitting layer EML is formed on the first electrode ED1 and the second electrode ED2 is formed to be electrically connected to the sub-electrode SUBE. The organic thin film layer EL is formed on the exposed first electrode ED1.

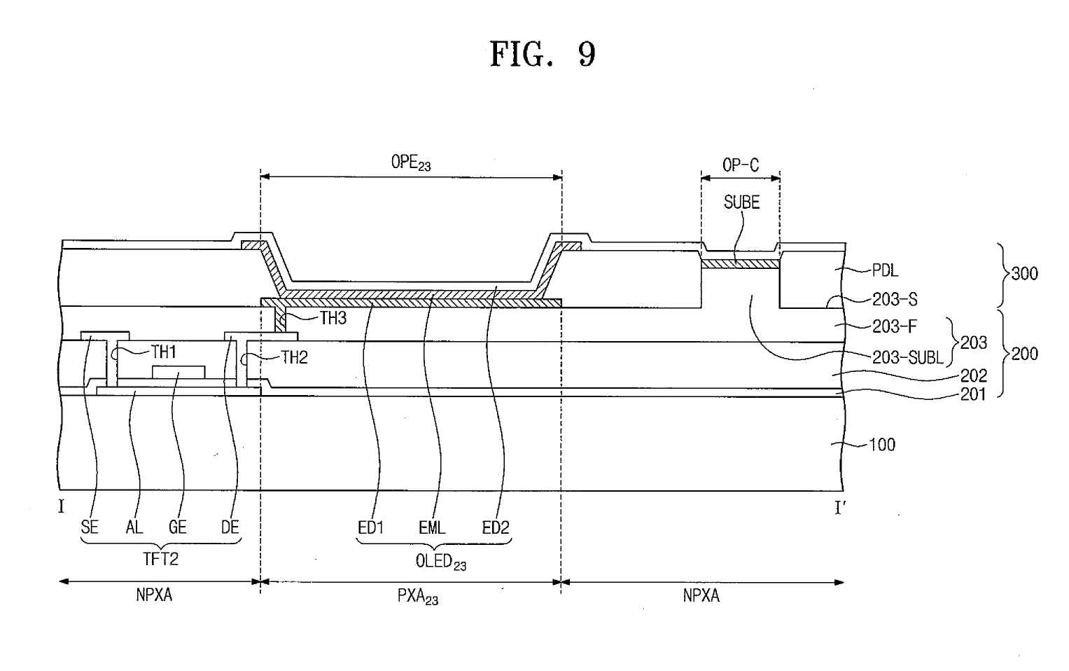

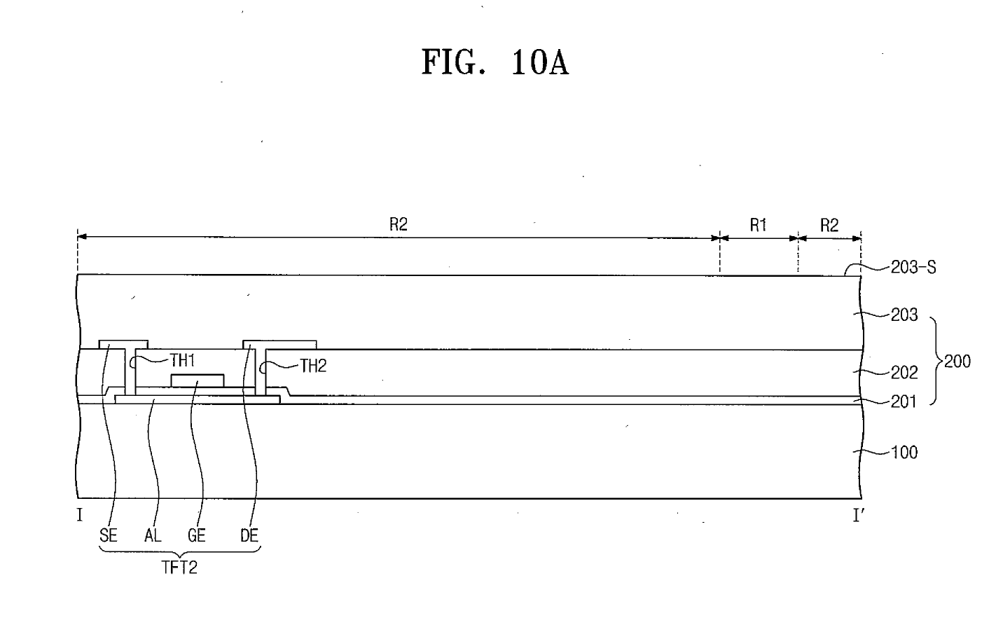

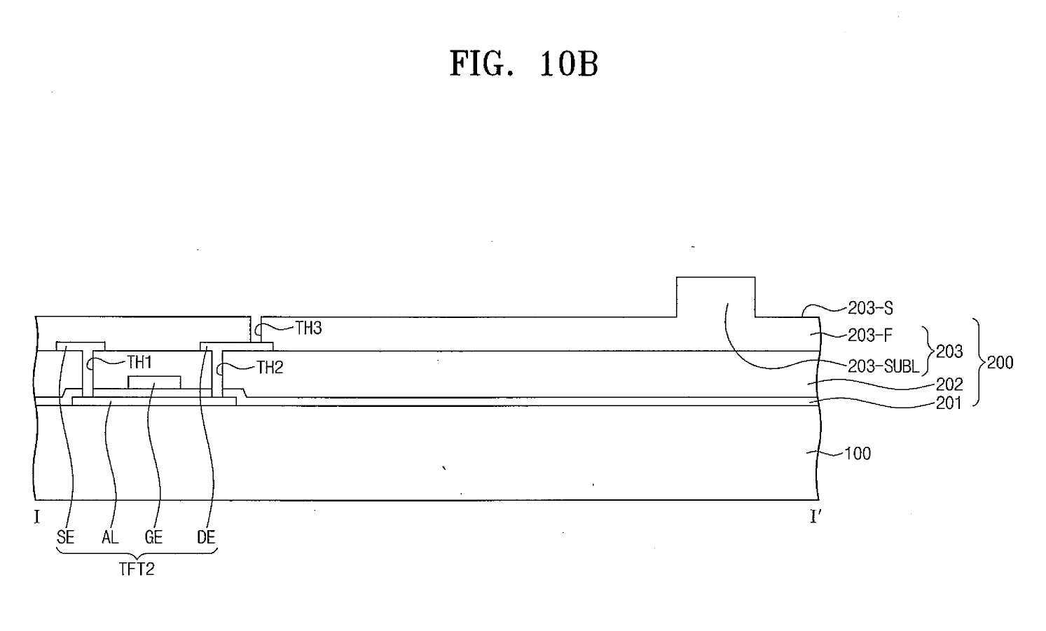

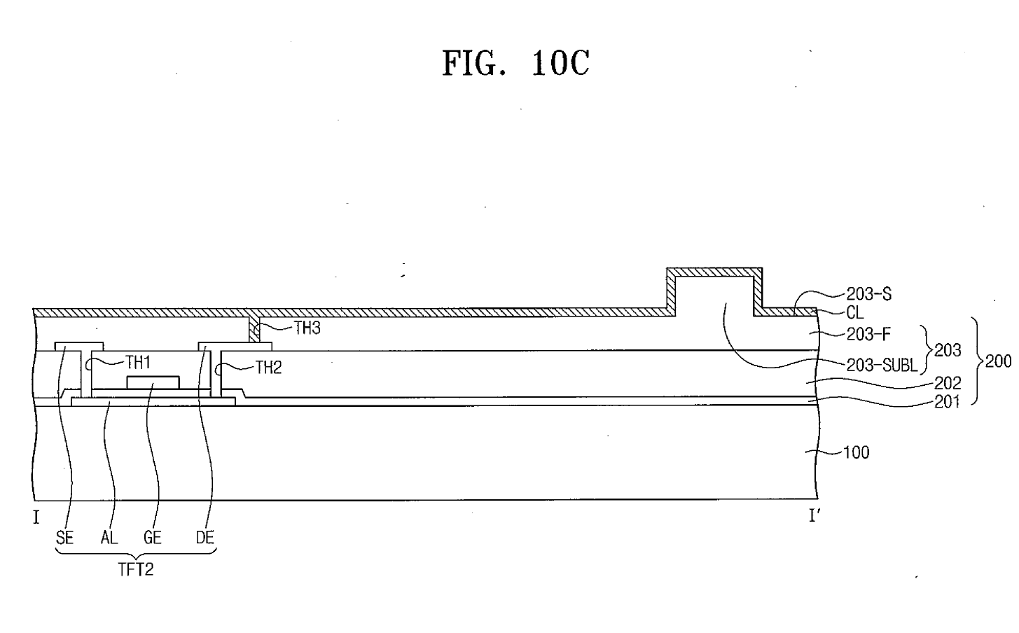

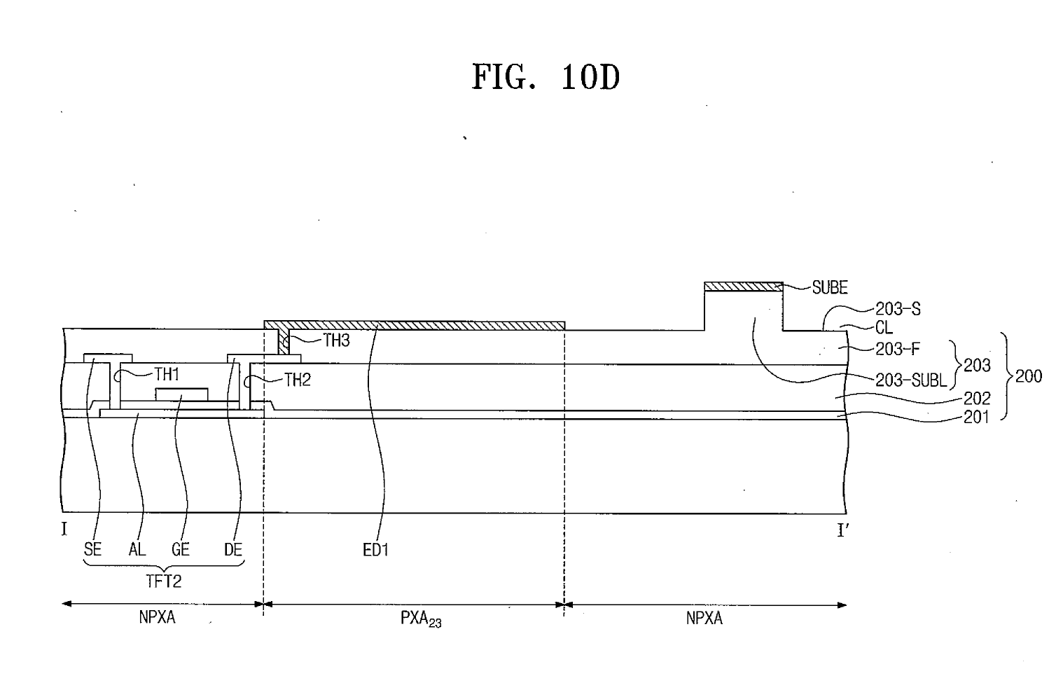

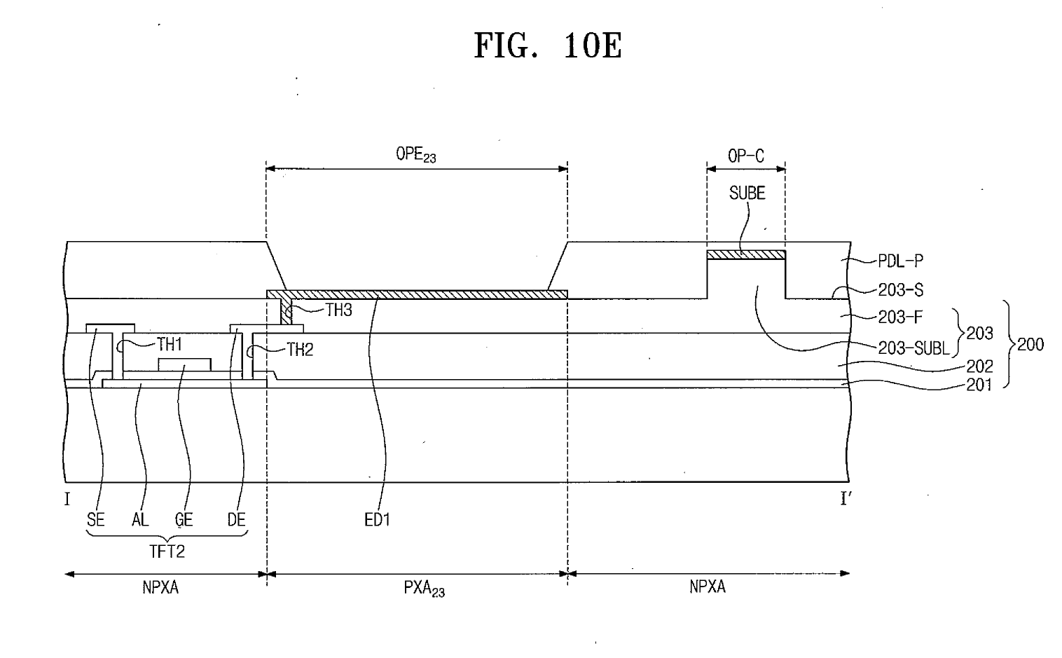

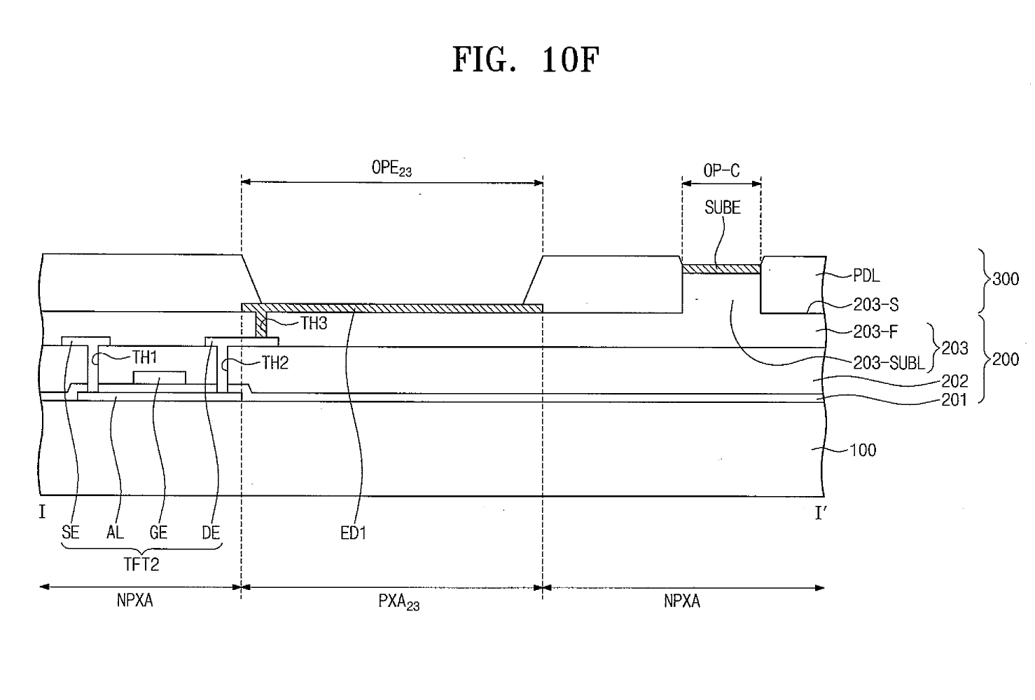

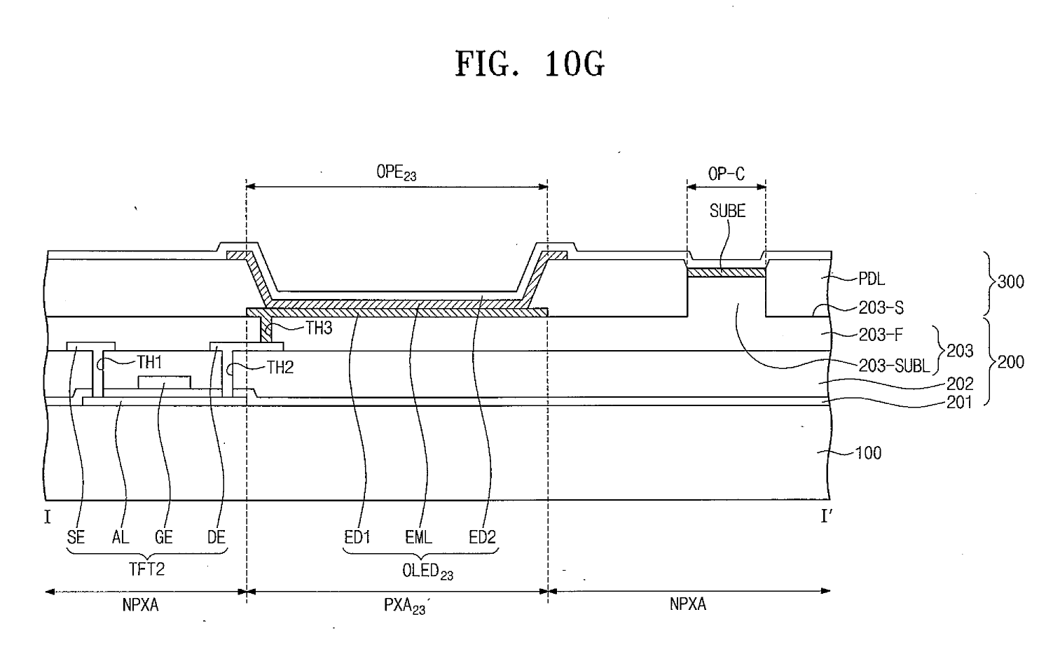

FIG. 9 is a cross-sectional view showing an organic light emitting display panel according to an exemplary embodiment of the present disclosure and FIGS. 10A to 10G are cross-sectional view showing a method of manufacturing an organic light emitting display panel according to an exemplary embodiment of the present disclosure. In FIGS. 9 and 10A to 10G, the same reference numerals denote the same elements in FIGS. 1 to 8H, and thus detailed descriptions of the same elements will be omitted.

Referring to FIG. 9, a supporting layer 203-SUBL and a base layer 203-F are integrally formed with each other. In other words, the supporting layer 203-SUBL and the base layer 203-F respectively correspond to different portions of one insulating layer. The base layer 203-F corresponds to a first portion of the insulating layer providing the base surface 203-S and the supporting layer 203-SUBL corresponds to a second portion of the insulating layer.

Referring to FIG. 10A, a preliminary insulating layer 203-S is formed on an insulating layer 202.

Referring to FIG. 10B, the preliminary insulating layer 203-P is partially removed to have different thicknesses according to its areas. Due to the process of removing the insulating layer, the supporting layer 203-F and the supporting layer 203-SUBL are formed from the preliminary insulating layer 203-P through exposure and development processes using a mask. The mask may be, but not limited to, a halftone mask. The halftone mask includes a transmissive area, a reflective area, and a transflective area adjacent to the transmissive area and the reflective area. The transflective area corresponds to a first area R1 and the transmissive area corresponds to a second area R2.

Referring to FIG. 10C, a conductive layer CL is formed on the insulating layer 203. The processes shown in FIG. 10D to 10G are substantially the same as those shown in FIGS. 8D to 8H, and thus details thereof will be omitted.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. An organic light emitting display panel comprising:
a base substrate;
a light emitting device comprising a first electrode, a light emitting layer on the first electrode, and a second electrode on the light emitting layer;
a base layer providing a base surface on which the first electrode is located;
a supporting layer protruding from the base surface;
a sub-electrode spaced from the first electrode, electrically connected to the second electrode, and located on the supporting layer; and
a pixel definition layer on the base substrate so as to expose the first electrode and the sub-electrode.

2. The organic light emitting display panel of claim 1, wherein a portion of the second electrode at which the second electrode contacts the sub-electrode overlaps with the supporting layer.

3. The organic light emitting display panel of claim 2, wherein the supporting layer comprises a supporting surface supporting the contact portion of the second electrode and the sub-electrode and an inclination surface inclined from the supporting surface.

4. The organic light emitting display panel of claim 3, wherein the sub-electrode overlaps with the supporting surface and the inclination surface.

5. The organic light emitting display panel of claim 1, wherein the supporting layer and the pixel definition layer are on the base surface.

6. The organic light emitting display panel of claim 5, wherein the supporting layer has a thickness substantially equal to the pixel definition layer.

7. The organic light emitting display panel of claim 1, wherein the sub-electrode comprises at least one of a first portion corresponding to one side of the first electrode and a second portion corresponding to the other side of the first electrode when viewed in a plan view.

8. The organic light emitting display panel of claim 7, wherein the supporting layer comprises at least one of a first pattern corresponding to the first portion and a second pattern corresponding to the second portion.

9. The organic light emitting display panel of claim 7, wherein the supporting layer comprises a plurality of island patterns overlapping the first portion or the second portion.

10. The organic light emitting display panel of claim 1, wherein the first electrode has a thickness substantially equal to the sub-electrode.

11. The organic light emitting display panel of claim 10, wherein the first electrode comprises a material that is substantially similar to the sub-electrode.

12. The organic light emitting display panel of claim 10, wherein layer structure of the first electrode matches a layer structure of the sub-electrode.

13. The organic light emitting display panel of claim 1, wherein the supporting layer and the base layer are integrally formed with each other in a single unitary and individual unit.

14. The organic light emitting display panel of claim 13, wherein the supporting layer comprises an organic material or an inorganic material.

15. A method of manufacturing an organic light emitting display panel, comprising:
forming an insulating layer comprising a first portion providing a base surface and a second portion protruding from the base surface on a base substrate;
forming a conductive layer on the insulating layer;
patterning the conductive layer to form a first electrode on the base surface and a sub-electrode spaced from the first electrode and disposed on the second portion;
forming a pixel definition layer on the base surface to expose the first electrode and the sub-electrode;
forming a light emitting layer on the first electrode; and
forming a second electrode electrically connected to the sub-electrode.

16. The method of claim 15, wherein the forming of the insulating layer comprises:
disposing a base layer providing the base surface on the base substrate to form the first portion; and
forming a second portion on the base surface.

17. The method of claim 16, wherein the forming of the second portion comprises:
forming a preliminary supporting layer on the base layer; and
removing areas of the preliminary supporting layer except for an area overlapping a portion at which the sub-electrode contacts the second electrode.

18. The method of claim 15, wherein the forming of the pixel definition layer comprises:
forming a preliminary pixel definition layer on the base surface; and
forming openings through the preliminary pixel definition layer to respectively expose the first electrode and the sub-electrode.

19. The method of claim 18, wherein an opening among the openings, which exposes the sub-electrode, is formed by a laser drilling method.

20. The method of claim 15, wherein the forming of the insulating layer comprises:
forming a preliminary insulating layer on the base substrate; and
removing the preliminary insulating layer in different thicknesses to allow the first and second portions to be formed from the preliminary insulating layer.
